(19) United States
(12) Patent Application Publication
(10) Pub. No.: US 2004/0029316 A1
(43) Pub. Date: Feb. 12, 2004

(54) Method for assembling planar workpieces

(76) Inventors: Anton Schnegg, Burghausen (DE); Robert Rurlander, Halsbach (DE); Markus Schnappauf, Rosenheim (DE); Thomas Hubel, Waldkraiburg (DE)

Correspondence Address: WILLIAM COLLARD, COLLARD & ROE, P.C., 1077 NORTHERN BOULEVARD, ROSLYN, NY, 11576, US

(21) Appl. No.: 10/415,597

(22) PCT Filed: Oct. 25, 2001
(86) PCT No.: PCT/EP01/12368

(30) Foreign Application Priority Data
Nov. 2, 2000 (DE) 100 54 159.3

(51) Int. Cl. H01L 21/44; H01L 21/48; H01L 21/50

(52) U.S. Cl. 438/118

(57) ABSTRACT

The invention relates to a method for assembling planar workpieces, whereby a connection, whose adhesiveness and brittleness is temperature-dependent, is made by means of a cement between the planar workpiece and a support plate. The method is characterised in that connected are only partially covered by the cement after the workpiece has been placed on the support plate.

The invention relates to a method for mounting planar workpieces, and in particular to a method for producing an adhesive bond between a semiconductor wafer and a support plate, a wax being used to produce a join which adheres and becomes brittle in a temperature-dependent manner between the semiconductor wafer and the support plate. The invention relates in particular to a method in which the semiconductor wafer is fixed to a support plate in order to prepare for single-side polishing.

Polishing is generally the final working step which is used to eliminate unevenness which has remained on the side faces of the semiconductor wafer. This unevenness originates from previous working steps, such as lapping or grinding, which are used to shape the semiconductor wafers. The desired end product is a semiconductor wafer with sides which are as planar and parallel as possible which is suitable for the fabrication of electronic components. It is already known to fix semiconductor wafers on support plates so that they can be processed, as described, for example, in DE-A 19756614. One possibility is for the wafer to be held in a guide (ring), the support—generally a foamed PUR pad or a sheet—being preformed by a very wide range of process variants. The second option is for the wafer to be sucked onto the reference surface by means of a vacuum, in which case there is frequently a risk of the seal not being perfect and therefore firstly of the wafer slipping and secondly of polishing abrasive reaching the back surface of the wafer and etching this surface. These types of wafer holder are preferably used for single-wafer processes. A drawback of this method is that the support is inaccurately defined as a reference plane.

In the second form of fixing, an adhesive is used, which fixes the wafer on a metallic or ceramic support with a high mechanical stability. This plane is simultaneously the reference plane for the geometry which is to be polished on the wafer. Two variants of this form are used.

A) During covering of the wafer with an adhesive, generally by spinning on the adhesive in a dissolved form, the surface of the adhesive is ultimately forced onto the surface of the support plate as reference surface after drying and heating into the molten range of the adhesive. In this case, unevenness of the wafer back surface is more or less completely concealed in the wax. A drawback of this method is the rheological behavior of the wax solution. Firstly, it is impossible to avoid a center artifact (defect) on account of the centrifugal process. Secondly, an edge bead will always build up at the edge of the wafer, and this bead cannot be completely eliminated by pressing the wafer onto the support. These problem zones are in geometric terms often detected in the 1/10 μm range.

B) When coating the support plate by spinning on the wax solution, in principle the same problem zones may form, but the support plate is generally not covered with wafers in the center or in the critical edge region, and consequently these defects are not transferred to the wafer. A drawback of this method is that the unevenness in the nanometer range from the preceding processes which are still present on the back surface of the wafer cannot be pressed fully into the wax and are reproduced by the subsequent polishing on the wafer front surface. The same also applies to unevenness which forms during the drying of the wax and heating into the range of the sticking zone of the adhesive. This waviness, which is known as the nanotopology and has short-wave pitches in the millimeter range and height differences of up to 50 nm, is reproduced on the wafer front surface and has an adverse effect in subsequent processes used in component fabrication.

The invention achieves the object of improving the nanotopology of a semiconductor wafer which is polished on one side and, in particular, of avoiding a local elevation in the center of the semiconductor wafer (centermark defect).

The invention relates to a method for mounting planar workpieces, in which a join which adheres and becomes brittle in a temperature-dependent manner is created by a wax between the planar workpiece and a support plate, wherein the surfaces of a support plate and of the planar workpiece which are to be joined, after the workpiece has been laid onto the support plate, are in each case only partially covered with wax.

According to the invention, the aim is not to produce a layer of wax which is completely cohesive over the entire area between the semiconductor wafer and the support plate. Rather, wax-free zones are also to be provided between the semiconductor wafer and the support plate. This procedure has various advantageous effects. Firstly, compressed wax can spread out into wax-free spaces when the semiconductor wafer is pressed onto the support plate. The same also applies to air, which can no longer be included in the wax. Possible differential pressure differences when the semiconductor wafer is pressed on are compensated for. Disruptions caused by particles are less common and centermark defects simply no longer occur. In general, systematic errors caused by spinning technology (e.g. pictureframing) are avoided.

Examples of the planar workpieces used in the method according to the invention are semiconductor wafers and workpieces which are to be polished with a high surface planarity, such as for example for optical systems, semiconductor wafers being preferred, and silicon wafers being particularly preferred.

In the method according to the invention, all mixtures of substances which have a temperature-dependent adhesive action can be used as the wax. Examples of waxes of this type are copolymers based on pyrrolidone and mixtures of substances based on colophony resin, as have previously been used, for example in methods for mounting semiconductor wafers on support plates.

The wax used in the method according to the invention is preferably a mixture of substances containing colophony resin which has been saponified with amine, at least one of the radicals on the amine being an aliphatic alcohol residue, and the boiling point of the amine at a pressure of 1000 mbar being greater than 150° C., if appropriate in a mixture with fillers.

Examples of the colophony resins contained in the wax used according to the invention are any commercially available colophony resins, such as for example those marketed under the trade name M-1XX by Arizona Chemical, USA, where XX is a sequential product number. The colophony resin is preferably obtained by vacuum distillation from crude tall oil and is chemically modified and esterified. It is preferable for the colophony resin to be chemically modified by reaction with a compound selected from the group consisting of maleic acid, maleic anhydride and fumaric acid. Then, the modified resin is esterified with an alcohol, which is preferably selected from a group consisting of glycerol and pentaerythritol. The chemically modified and esterified colophony resin preferably has an acid number of from 50 to 250 [mg KOH/g of resin], a softening point of 60 to 180° C. and a molecular weight M_{w} (weight average) of from 1200 to 4000.

The amines with which the chemically modified and esterified colophony resins can be saponified are preferably aqueous solutions of triethanolamine, triisopropanolamine, diisopropanolamine or diethanolamine, in which case the resin soap is dissolved in the aqueous phase.

The amount of solvent, such as water or organic solvent, used to produce the wax used in the method according to the invention is dependent on the desired viscosity for the application process.

Examples of fillers which can be used to produce the wax used in the method according to the invention are soots, pigments, TiO₂, Fe₂O₃, CeO₂, rutile, anatase, SiO₂ sol, highly dispersed silica, organic polymers, such as polyethylene, polypropylene, polyamide or polyurethane, in particular in powder form, thixotropic polymers, derivatized carbohydrates, cellulose and cellulose ether. The type of filler used to produce the mixture of substances according to the invention is dependent, inter alia, on the desired degree of hydrophilicity and/or on the mechanical hardness of the adhesive layer.

The waxes used in the process according to the invention are anhydrous and water-containing mixtures of substances with the following composition:

10 to 100% by weight of chemically modified and esterified colophony resin completely saponified with amine,

0 to 10% by weight of inorganic filler,

0 to 2% by weight of auxiliaries, such as surfactants, alcoholic solubilizers and colorants, and

water in a quantity which makes up the sum of the quantitative data to 100% by weight.

If surfactants are used in the mixture of substances according to the invention, in particular to adapt to the desired sticking zone range, an arrangement which is not preferred, these are preferably nonionic surfactants, in particular nonyl phenol polyethers, which can act as plasticizers.

If alcoholic solubilizers are used in the mixture of substances according to the invention, in particular to accelerate dissolution, an arrangement which is not preferred, the solubilizer is preferably isopropanol.

If colorants are used in the mixture of substances according to the invention, in particular to allow visual monitoring of the layer thickness, the colorants are preferably crystal violet, fluorescent dyes, such as Rhodamine B and Eosin, and intensively coloring water-soluble colorants, such as malachite green.

The mixture of substances according to the invention particularly preferably comprises:

25 to 100% by weight of chemically modified and esterified colophony resin completely saponified with triethanolamine,

0 to 10% by weight of inorganic filler,

0 to 2% by weight of auxiliaries, such as surfactants, alcoholic solubilizers and colorants, and

water in a quantity which makes up the sum of the quantitative data to 100%.

In the method according to the invention, the wax may be applied either to the surface of the support plate or to the surface of the planar workpiece, i.e. preferably of the semiconductor wafer. The wax may also be applied both to the support surface and to the surface of the semiconductor wafer, although this is not preferred for reasons of process economy. The support plate used in the method according to the invention may, in terms of size and geometry, correspond to the semiconductor wafer which is to be fixed. However, the support plate used may also be larger than the semiconductor wafer which is to be fixed, so that a plurality of semiconductor wafers can be fixed simultaneously on a support plate, which is preferred.

In the context of the present invention, the term large support plate is to be understood as meaning a support plate on which a plurality of semiconductor wafers can be fixed, particularly preferably having a diameter which is 2 to 4 times that of the semiconductor wafer.

If a large support plate is used, the entire surface may be covered with wax, or alternatively only the regions onto which the semiconductor wafers are subsequently to be placed may be coated with wax. The latter has the advantage that less wax has to be used and that the tools used are small and therefore easier to operate. However, depending on the particular application conditions, it may also be advantageous for the entire support plate to be coated if, for example, this in specific instances leads to the work satisfying clean room conditions more fully.

In the method according to the invention, coating a large support plate with wax has the advantage that a plurality of semiconductor wafers can be fixed using one coating. Coating the individual semiconductor wafer has the advantage that the size of the auxiliary equipment used can be selected to be smaller, which entails a reduced outlay on equipment. Therefore, in the method according to the invention, the wax is preferably applied to the semiconductor wafer, with the proviso that the surfaces of the support plate and of the semiconductor wafer which are to be joined, after the semiconductor wafer has been placed onto the support plate, are in each case only partially covered with wax.

In the context of the present invention, the term surface to be joined, with regard to the semiconductor wafer means the side face by means of which the semiconductor wafer rests on the support plate, and with regard to the support plate means the part of the surface which is covered by the semiconductor wafer lying on the support plate.

In the method according to the invention, preferably at most 75% of the surfaces to be joined is covered with wax. The lower limit is arbitrary, but generally results from stability criteria during fixing. There must be sufficient wax to ensure that the semiconductor wafer does not come off the support plate during the polishing. In the method according to the invention, it is particularly preferable for from 10 to 50% of the surfaces to be joined to be covered with wax.

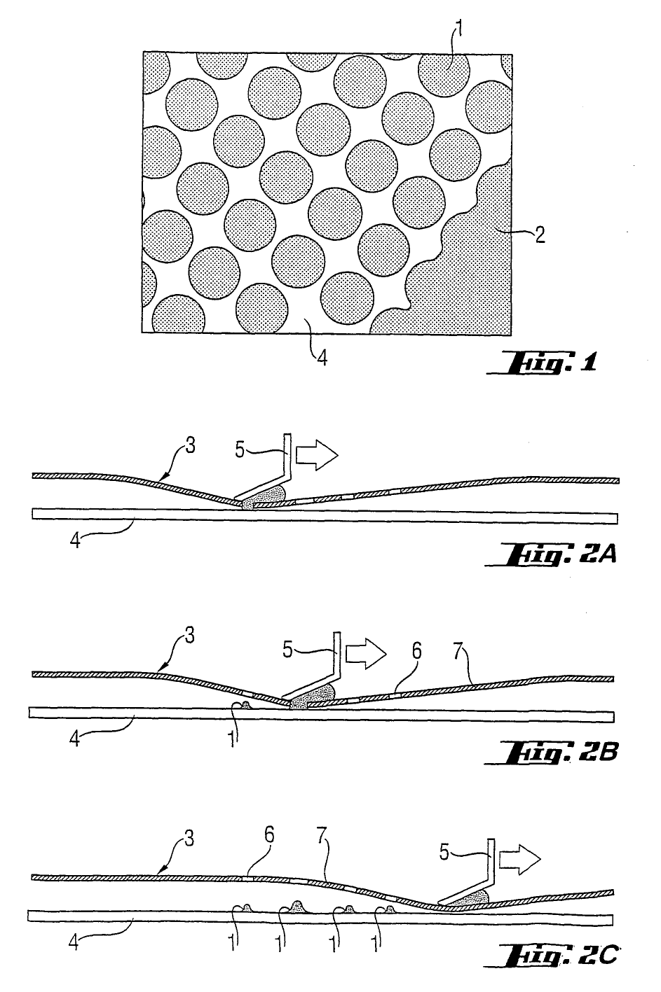

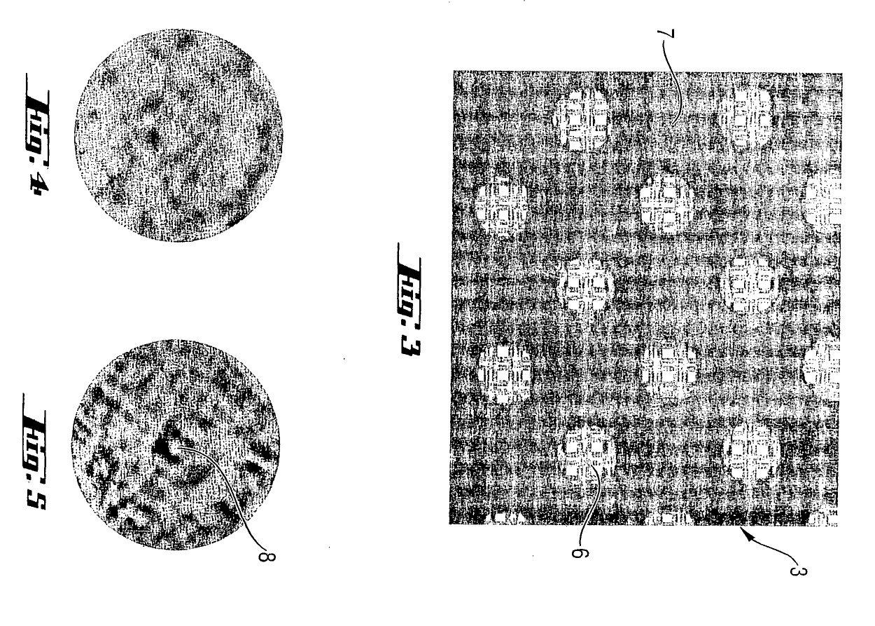

The following text describes possible embodiments of the method according to the invention. Furthermore, a particularly preferred embodiment is explained in more detail with the aid of figures. FIG. 1 shows a preferred distribution of spots of wax. FIG. 2 illustrates the principle of screen printing in accordance with the preferred method variant d). FIG. 3 shows a microscope image of a screen which is suitable for carrying out this method variant. FIGS. 4 and 5 provide a comparative illustration of the results of a nanotopological examination of the surfaces of two semiconductor wafers, only the semiconductor wafer shown in FIG. 4 having been polished in accordance with the invention.

Method Variant a):

In method variant a) according to the invention, the wax which is to be used is heated until it is of a pourable consistency, which preferably corresponds to a viscosity of from 1000 to 100,000 mm²/s, particularly preferably 10,000 to 100,000 mm²/s. The temperature at which the wax has a viscosity within this range preferably lies above the sticking zone, where the viscosity generally changes considerably with the temperature. The term sticking zone is intended to mean the temperature range within which the wax presents its most effective adhesive action. The maximum temperature used in the method according to the invention should not exceed 110° C., since over a prolonged period initial decomposition products are formed, which may have an adverse effect on the adhesive properties. In the method variant a) according to the invention, the heated wax is then applied to the surface to be coated using a conventional toothed doctor, as is known, for example, in the sector of chemicals for the building industry. The particular viscosity selected for the wax allows the film thicknesses of the wax to be adjusted particularly easily, preferably in the range from 1 to 50 μm. During the application, particular attention is to be paid to the geometric perfection of the doctor or the guidance of the doctor in the lateral direction. In the method variant a) according to the invention, turning the support plate beneath the doctor has proven to be a simpler variant. In this case, the edge region of the support plate is coated more uniformly than the center. The center is generally irrelevant when using large support plates for polishing, since the center is generally not provided with a semiconductor wafer. In the method variant described, the wax forms a covering of strips which run parallel to one another and are separated by wax-free regions.

Method Variant b):

In method variant b) according to the invention, the wax is rolled out externally between two separating papers, the wax, with the aid of thermal energy—as described in method a)—being set to a plastic consistency which preferably corresponds to a viscosity of 50,000 to 200,000 mm²/s,. particularly preferably 70,000 to 150,000 mm²/s, and being processed into films with a thickness of preferably 5 to 50 μm. After one of the separating papers has been removed, the film obtained in this way is rolled onto the substrate (the semiconductor wafer or the support plate) by means of a profiled roller and the second separating film is pulled off.

In method variant b) according to the invention, the thickness tolerances of the layers of wax achieved in long-wave form are preferably <<1 μm. On account of their long-waved nature, which originates from the geometry of the roller and the fact that the support plate is transported through the pair of rollers, these fluctuations in thickness do not disrupt the overall geometry of the wafers. There are no nanotopological effects with waviness of a few mm and heights of 10 to 50 nm.

Method Variant c):

In method variant c) according to the invention, the wax is used in powder form with a grain size spectrum of preferably 0.5 to 5 μm, particularly preferably 0.5 to 4 μm. One example of wax which can be used is a wax with a grain size spectrum of 0.5 to 1.0 μm for relatively thin layers of wax and 2.0 to 5 μm for thicker layers of wax. The wax powder which is used according to the invention can be obtained using known methods, such as precision grinding plus classification or using a spray plate and precipitation from a wax solution. In the latter case, it is preferable to use a solution of wax in water which is precipitated using strong mineral acid, such as HCl or H₂SO₄. The support plate—or more simply the semiconductor wafer—is electrostatically charged to >>10 kV in method variant c) according to the invention.

The wax powder is oppositely charged in a fluidized bed and is blown over the surface to be coated, by means of a spray pistol, in a dilution of 1:1000 to 1:10,000 in a propellent gas, so that part of the surface to be coated is covered with wax. On account of the strong attraction between the particles and the substrate and the strong repulsion between the particles, assisted by the high dilution, a layer of monodisperse particles is formed. As a result of the temperature being increased in method variant c) according to the invention, the wax is brought into the sticking zone and is pressed onto the preheated, uncoated support plate or semiconductor wafer. An advantage of coating the support plate is the lower cost in relative terms, since one coating can be used to mount a plurality of wafers. By contrast, coating the individual semiconductor wafer has the advantage that the equipment can be considerably smaller and can provide better protection against additional particle contamination. This is highly significant, since the embedding of relatively large particles inevitably leads to dimples which would make the wafers unusable.

The particularly preferred method variants d) and e) involve printing techniques which are used to apply the wax. A common feature of these techniques is that the wax can be applied at selected locations on preferably the semiconductor wafer or, if appropriate, alternatively the support plate. When seen from above, the printed patterns of wax preferably have the appearance of islands in the form of spots. The islands have a defined diameter, a defined density, which if appropriate may differ locally, and a defined, selected height. The spot density is preferably from 10 to 100 spots/cm, particularly preferably from 10 to 40 spots/cm. The spot diameters are preferably in a range from 50 to 500 μm, particularly preferably from 50 to 400 μm. The spot height is preferably from 1 to 20 μm, particularly preferably 2 to 5 μm. The diameters, heights and shapes of the spots of wax can be adjusted in particular by means of the viscosity and the flow behavior of the wax and the printing technique employed. The spacing between the spots is selected according to stipulations with regard to spot density, spot height and spot diameter. The spots of adhesive may be distributed uniformly over the printed surface. According to a preferred embodiment of the invention, the diameters of the spots of wax in an edge region of the semiconductor wafer are larger than in a central region of the semiconductor wafer, or if spots of wax with a constant diameter are used, the density of the spots of wax in the edge region of the semiconductor wafer is higher than in the central region. Finally, the spots of wax in the edge region of the semiconductor wafer may also form a continuous film of wax. This is particularly advantageous in the case of water-soluble waxes, since the abovementioned measures prevent the spots of wax from being partially dissolved or undermined by the penetration of moisture, for example by the penetration of polishing abrasive. FIG. 1 shows a region of uniformly distributed spots of wax 1 and an edge region at which the spots of wax have fused together to form a cohesive film of wax 2.

A preferred embodiment of the invention provides for the local supporting of the semiconductor wafer using spots of wax to be selected in such a manner that the semiconductor wafer deliberately acquires a convex or concave form as a result of the polishing. This is particularly preferred if the polishing is followed by haze-free polishing without significant removal of material (mirror polishing) or another single-side treatment or coating which changes the form of the semiconductor wafer and the change in form leads to it being possible to regard the semiconductor wafer as having ideal planarity at the end of the process sequence.

According to a further preferred embodiment of the invention, the form of the semiconductor wafer which is to be polished is examined, and those locations which are to be preferentially abraded during the subsequent polishing are determined on that side of the semiconductor wafer which is to be polished. The wax is then applied preferentially or to an increased extent opposite said locations on the side of the semiconductor wafer which is joined to the support plate. This measure also aims to obtain a semiconductor wafer with a surface which has been polished until it is as planar as possible.

Method Variant d):

In method variant d) according to the invention, the wax is applied as a highly viscous mass using the screen-printing technique by using a squeegee to print it through a structured screen and in the process is preferably printed onto the semiconductor wafer. The wax has a viscosity in the range from preferably 5 to 100,000 mm²/s, particularly preferably 50 to 10,000 mm²/s, in each case based on 25° C. The dimensions of the screen, of the block (screen base body), and the flow properties of the wax mass must match one another. Further variables which influence the result of printing are the screen material and its lift-off performance, the mesh width and the filament thickness. For the screen, it is possible to use both plastic filaments, for example polyester filaments, and metal filaments, for example steel or brass filaments. When selecting the screen, it should be ensured that the ratio of the impermeable locations produced by means of photoresist to the regions which are permeable to the wax is large enough for the spots of wax to be clearly separated from one another. On the other hand, the spots of wax must be close enough together to ensure that a pattern of the spots of wax is not transferred to the polished surface of the semiconductor wafer during polishing of the semiconductor wafer.

The principle of the screen-printing method is illustrated in FIG. 2. The following sequence has proven particularly appropriate. The structured screen 3 is arranged above the substrate 4, preferably above that surface of the semiconductor wafer which is to be joined to the support plate. During the printing operation, the screen is not laid onto the substrate, but rather is held at a short distance from the substrate as a function of the properties of the wax. After the screen has been filled with wax by means of a filling squeegee, in a further step the volume of wax located in the screen is pressed onto the substrate 4 by means of a printing squeegee 5. The screen cloth, which has been greatly extended in the process, lifts off the substrate immediately behind the squeegee and produces a very uniform printed image comprising spots of wax 1, the spacing and arrangement of which have been predetermined by the block. FIG. 3 shows a suitable screen 3. The round areas 6 which wax can pass through (passage spots) can be clearly differentiated from the regions 7 through which wax is unable to pass. The distance of the screen from the substrate (“lift”) can be adjusted as a function of the viscosity of the wax used and the size of the passage spots in the block. It is preferable for the screen only to touch the surface of the semiconductor wafer in punctiform fashion when the wax is being applied by the squeegee. The height of the layer of wax is adjusted by means of the proportion of solvent in the wax mass and the height of the spots of wax, the shrinkage being proportional to the quantity of solvent evaporated.

Tests have shown that wax dissolved in solvent, preferably in water, within the viscosity range of approximately 50 to approximately 10,000 mm²/s can be used without problems at room temperature without an elevated temperature having to be employed in order to reduce the viscosity. This corresponds to water contents of approximately 65 to 40% by weight, based on the overall mass of the wax formulation. As the water content increases, and the viscosity decreases accordingly, the wax mass shrinks, resulting in different end forms depending on the viscosity of the wax. In the case of waxes with a relatively high viscosity, a spot of wax has a column-like structure, while wax solutions with a low viscosity tend to produce spots of wax which look like hemispherical domes. Low-viscosity wax solutions are particularly suitable if thin layers of adhesive are desired. In general, the flow performance of the wax after the application by means of screen printing can also be influenced by additionally adding surfactant, for example triethanolamine, to the wax formulation. Although this further reduces the sticking zone, with the result that the adhesive action at low temperatures is increased, when removing the wax from the wafers this has only a minor effect, since the area to be separated corresponds to only part of the side face of the semiconductor wafer.

Since the application using a squeegee constantly generates a new large area of the wax, the viscosity of the wax mass increases continuously as the solvent evaporates. A higher viscosity leads to a lower degree of shrinkage and therefore a higher application of wax. This may be perfectly desirable. For reliable and constant process management, however, the viscosity of the wax should be kept within as tight limits as possible, since this also prevents the wax from beginning to dry on the screen. This is preferably achieved by the screen being shielded from the environment by means of a hood and, if appropriate, the internal space which forms having additionally humidified air flushed over it. When using a water-soluble wax, a constant water-vapor pressure of preferably 6 kg/m³ of air is particularly preferred. The consistency of the viscosity can be maintained more easily by continuously replacing the quantity of wax which has been lost as a result of the printing operation with a wax which is more dilute by the amount of evaporated water or solvent. In continuous operation this controlled arrangement is very simple, since the amount of wax consumed is constant and can easily be determined by weighing.

Another possible option for maintaining a constant viscosity of the wax consists in using a wax which is free of solvent. The viscosity is set by controlling the temperature of the wax. This is advantageously achieved by direct current passage through a metallic screen. The temperatures required are in this case briefly in the range from 60 to 115° C., corresponding to a viscosity of 100,000 to 30,000 mm²/s.

It is recommended for the screen to be cleaned regularly, since even under clean-room conditions particles which are still present can block individual pores of the screen and therefore disrupt the printed image. On account of the high number of spots with respect to the unit of surface area, the failure of an individual spot of wax does not yet have any geometric or nanotopological effect on the polished semiconductor wafer, but should nevertheless be avoided in order to achieve an excellent quality level. Therefore, it is preferable for the screen to be cleaned regularly. A suitable cleaning agent is in particular a solvent which dissolves the wax, a rotating brush as cleaning tool accelerating the cleaning. It is considerably easier to use rotating brushes as cleaning tools, for example rotating brushes used in standard domestic dishwashers. Particularly when using water as solvent, cleaning can be made very easy by partially dissolving the wax by circulation, and washing it away using fresh water or another solvent. In order for the screen subsequently to be dried, by way of example air or nitrogen is blown through the same rotating nozzle system or, preferably, through a separate nozzle system which is adapted to the lower viscosity of the gas. When introducing a new or cleaned screen, the first print run may lead to an uneven application of wax. To reliably prevent this, the first print run is preferably carried out on dummy wafers, paper or a sheet until the printed image has the required quality. It has proven particularly advantageous to use a sheet.

As an alternative to the screen-printing technique described above, it is possible to employ related methods, such as for example letterpress printing or the particular embodiment of flexographic printing, in which the adhesive is transferred to the substrate to be printed from a rotary reservoir with a specifically set number and depth of cups via a roller which bears the block of spots.

In method variant d) according to the invention, the preferred printing of the semiconductor wafer also has the advantage that the thermal mass for evaporation of the solvent is significantly lower than when printing a large support plate. However, care should be taken to ensure that the surface of the semiconductor wafer which is to be polished is not damaged during the coating according to the invention.

Method Variant e):

In method variant e) according to the invention, the wax is applied as a highly viscous mass using the inkjet printing method. The viscosity of the wax is dependent on the nozzle spacing of the printhead and is set in such a way that the individual spots of wax do not touch one another and even under the pressure of the wafer still leave sufficient space for included air to be able to escape and unevenness of the wafer to be compensated for by flowing of the wax.

The viscosity can be set by means of solvent, such as for example organic solvent, such as for example isopropanol or toluene or water, water being preferred. In this case, it should be borne in mind that the spot of wax shrinks during the subsequent drying step and therefore its dimensions change by the factor of the percentage of solvent added. In the process, the shape of the spot of wax is only changed slightly, while the basic shape, which is generally a symmetrical rounding of the tip, remains substantially the same.

A further embodiment of method variant e) according to the invention consists in the use of a solvent-free wax, the viscosity of which is set to a desired value by controlling the temperature in the printhead. This procedure has the advantage that a separate drying step and the resulting change in shape and volume do not occur.

Standard inkjet heads, in which the spots of wax are characterized by the dpi (dots per inch) and wax-spot spacings of approx. 40 μm (20 μm) can be produced, may be used. In general, the spacing and size of the spots of wax can be adjusted by means of the size and number of piezoelectrically actuated printing nozzle and the actuation of the printhead. Spacings of >1 mm are to be avoided, since in this case the bending of the semiconductor wafer alone generates a slight waviness (nanotopology).

In method variant e) according to the invention, the viscosity of the wax used is preferably 5 to 100,000 mm²/s, particularly preferably 50 to 10,000 mm²/s (solvent-containing wax), in each case at 25° C. for water-containing wax, or 10,000 to 100,000 mm²/s at 60 to 115° C. for solvent-free wax.

In the method according to the invention, after the surfaces to be joined have been coated in accordance with one of the proposed method variants a) to e), it is possible for the further procedure to be in accordance with the known operating methods. The coating which has been produced according to the invention dries to form a mass which adheres and becomes physically brittle in a temperature-dependent manner. The adhesive action of the mass is produced only within a narrow temperature range (sticking zone) of preferably 40 to 80° C. As with a hot melt adhesive, the adhesive action decreases if the mass is heated to above an upper temperature of the sticking zone. The adhesive action also decreases at temperatures below the sticking zone. To produce, in accordance with the invention, a join which becomes brittle between a semiconductor wafer and the support plate, the support plate is heated to a temperature of preferably 60 to 120° C., and then the semiconductor wafer is placed onto the heated support plate and after a few seconds (heating of the wafer) is pressed onto the support plate using a suitable tool. As the support plate and wafer cool to a temperature which lies slightly below the sticking zone, the mass is cured, thus creating a fixed join between the semiconductor wafer and the support plate. It is also possible to heat the semiconductor wafer instead of the support plate and to lay the semiconductor wafer on the support plate in the hot state.

The join produced in this way retains its strength even under the temperature conditions of preferably 30 to 50° C. which usually prevail during polishing.

It is preferable for a plurality of semiconductor wafers, for example six wafers, to be laid onto a support plate and to be pressed onto the support plate together or in groups. The semiconductor wafer is preferably placed onto the support plate by being sucked on in an edge region and being dropped onto the preheated support plate in a convexly deformed state, after which a central area is pressed onto the support plate with the aid of an inflatable pressure chamber.

The semiconductor wafers may be pressed onto the support plate by means of a large plate used as a ram, but it is difficult to align the plane of the ram parallel to the support plate, requiring intelligent control. It is more appropriate to use a diaphragm which extends over all the semiconductor wafers and transfers the required force to the semiconductor wafers, for example by means of gas pressure. It has proven particularly easy to use inflatable bellows which, with suitable pressure control, apply the forces very uniformly to the wafer surface. It is even easier and even more effective for the pressing to take place using a pad, such as that used in pad printing. This pad is, for example, a silicone cushion of very low hardness, which is in the range from 2 to 20 Shore A, preferably between 2 and 12 Shore A. The pad is expediently provided with a shallow conical tip or a rounded tip, in order to achieve an optimum pressure distribution over the surface of the semiconductor wafer. The bellows or pad is expediently arranged at an offset of 120°, so that in each case 3 semiconductor wafers can be pressed simultaneously. In principle, it is also possible to apply the pressure to individual wafers, but this is not preferred in view of the flow of the process. The pressure range used when operating with a pressure bellows or pad is between 50 and 1000 mbar, preferably between 50 and 500 mbar. It is also possible to use pressures of from 1 to 5 bar, but such pressures do not provide any additional benefit.

After the polishing of the semiconductor wafer, the join between the semiconductor wafer and the support plate can be detached again. This is preferably effected by introducing a suitable tool, similar to a spatula or a knife blade, into the adhesive join and using the lever action to release the semiconductor wafer. With the waxes which are described above as being preferred and particularly preferred, water, in particular in combination with megasound (600 to 1500 kHz), is able to dissolve the residues of the mixture of substances from the semiconductor wafer and the support plate without leaving any residues.

The method according to the invention is distinguished in particular by the fact that layers of wax can be produced on surfaces which are to be joined in a simple and highly accurate manner, and physical peculiarities which lead to defects are avoided.

The method according to the invention has the advantage that the layer of wax is structured in such a way during application that both the unevenness of the wafer back surface and the unevenness of the dried wax can escape into the cavities between the “spots of wax” when the wafer is pressed into the wax.

The method according to the invention has the advantage that the unevenness of the preliminary product and the vapors which are formed when the wax dries from its solution can be buffered in the spaces between the wax applied in the form of spots.

Furthermore, the method according to the invention has the advantage that it does not leave any waviness in the submicrometer range on the surface of the polished semiconductor wafer.

Furthermore, the method according to the invention has the advantage that, despite a low sticking zone range, the wax is so inelastic at the selected polishing temperatures that the wafers do not shift and in that during the removal of the wax (during release of the adhesive bond), the force required can be reduced considerably compared to an adhesive bond produced over the entire surface, to approx. ⅓ to ⅕ of the former level depending on the density of the spots.

The method according to the invention has the advantage that even wafers of large diameters and therefore correspondingly large surface areas can be fixed without problems of air being included beneath the wafer, of the wafers shifting or of waviness.

The method according to the invention has the advantage that the shrinkage of the wax as a function of the solvent content—which is the principal factor involved in the nanotopological deformation of the semiconductor wafer when wax is applied to the entire surface—is reduced considerably.

The method according to the invention has the advantage that there is no deformation in the edge region of the fixed wafers, as is known to occur in the case of adhesive bonding over the entire surface.

In the examples which follow, all information about parts and percentages are by weight, unless stated otherwise. Unless stated otherwise, the following examples are carried out at the pressure of the surrounding atmosphere, i.e. at approximately 1000 hpa, and at room temperature, i.e. approximately 22° C. or a temperature which is established when the reactants are combined at room temperature without additional heating or cooling.

The following abbreviations are used:

SP=support plate made from aluminum oxide ceramic with a diameter of 640 mm.

MM=magic mirror

### COMPARATIVE EXAMPLE 1

An approximately 30% strength aqueous solution of the wax—produced by dissolving 3.6 kg of colophony resin Bergvik M-106 in 13.9 kg of deionized water with the addition of 1.47 kg of triethanolamine (80% by weight in water), 450 g of nonylphenolpolyether, 1.96 kg of isopropanol and 10 g of crystal violet—was applied by centrifugal methods to an SP so that, after drying at 45° C., a continuous layer with a thickness of 6 μm was produced. After further heating of the SP to a uniform surface temperature of 75° C., a silicon wafer with a diameter of 200 mm was placed on the SP using a vacuum suction device and was pressed into the wax under a pressure of 300 mbar. After the polishing of the silicon surface, the wafer was detached from the SP, cleaned and the local planarity of its surface was investigated by means of MM. Large, roundish differences in brightness with a length of a few millimeters (8 to 15 mm) were found. The height of the formations was determined to be up to 60 nm using the SQM appliance produced by KLA-Tencor.

### EXAMPLE 1 (Method Variant a))

The anhydrous wax—produced by melting down 8.9 kg of colophony resin M-108, 4.2 kg of triethanolamine (80% by weight in water) and 25 g of crystal violet until the components were fully dissolved and evaporating the water until the weight remains constant—was poured onto the preheated SP at 100° C. and was uniformly distributed over the surface using a toothed doctor (doctor width 210 mm, the teeth with a width of 250 μm and a spacing of 250 μm), so that approximately 50% of the surface was covered with wax in strip form. The height of the strips of wax was 50 μm. The further steps took place as described in Comparative Example 1. The MM revealed long-wave, oriented structures (20 to 40 mm) which originated from the guidance of the doctor. The structures attributable to the wax process were determined to be up to max. 25 nm high.

### EXAMPLE 2 (Method Variant b))

In a laboratory installation, the molten wax, which was produced as described in Example 1, with a viscosity of 150,000 mm²/s was rolled out over a large area a number of times between two siliconized separation papers, in order to obtain a film thickness of 30 μm which is as uniform as possible. After one separation paper had been pulled off, the film was rolled onto an SP at 80° C. by means of a profiled roller, approximately 50% of the surface of the SP being covered with the wax film in strip form. The height of the strips of wax was approximately 50 nm. The application of the wafer and the further processing took place as described in Comparative Example 1. The MM recorded strips of different wafer thickness which corresponded to the spacing of the roller profile. The height of the actual waviness was measured at max. 25 nm.

### EXAMPLE 3 (Method Variant c))

The anhydrous wax, which was produced as described in Example 1, was milled to form a fine powder and was classified to 0.5 μm by “gas classification”. This powder, which can readily be electrostatically charged to at least 10 kV by internal friction in a fluidized bed, was then applied very thinly to the surface of the SP by immersion of the latter, so that virtually only a single-layer coating was effected and approx. 30% of the surface of the SP was coated with wax. After brief heating to the melting point, the wafer was put in place and processed as described in Comparative Example 1. The SQM determined the height of the nanotopology to be approximately 20 nm, but there were some dimples on the wafers, which is attributable to some colophony grains forming aggregates.

### EXAMPLE 4 (Method Variant d))

A metal screen with dimensions of 530×420 mm and a mesh number of 350, in the center of which an area with a diameter of 205 mm was provided with a pattern of spots (spot diameter 160 μm, spot spacing 160 μm) by means of a photoresist technique, was covered and squeegeed with a highly viscous wax mass (viscosity 46,000 mm²/s), produced from 500 g of a colophony resin M-108, 239 g of triethanolamine (80% by weight in water), 290 g of water and 2 g of crystal violet. The individual spots were substantially hemispherical, and approximately 25% of the surface of the wafer was covered with wax. The SP and wax were heated to 80° C. The application of the wafer and the further processing took place as described in Comparative Example 1. After removal of the wax and cleaning of the wafer, the surface of the semiconductor wafer was free of defects under the MM, and even the SQM was only able to detect slight differences in brightness, the height of which was measured to be 10 nm. FIG. 4 shows the image of a semiconductor wafer which had been polished in accordance with Example 4 generated by a surface inspection appliance with nanotopology resolution. For comparison purposes, FIG. 5 shows a corresponding image of a semiconductor wafer which was joined to the support plate by a continuous film of wax during the polishing. The lower-contrast appearance of FIG. 4 indicates that the unevenness is less pronounced. A centermark defect 8 which can be seen in the center of FIG. 5 is simply not present in FIG. 4.

### EXAMPLE 5 (Method Variant e))

A relatively low-viscosity wax (viscosity 22 mm²/s) which was produced as described in Comparative Example 1, was introduced into the emptied printhead of a Hewlett Packard DeskJet 500 printer. By forming a grid over a surface of 80 mm×80 mm, the individual spots of adhesive were applied to the preheated sample support plate with a diameter of 200 mm, and a 3″ Si wafer was positioned and processed using the method described in Comparative Example 1. The nanotopology quality was similar to that achieved in Example 4, with a height difference of 5 to 9 nm.

1. A method for mounting planar workpieces, in which a join which adheres and becomes brittle in a temperature-dependent manner is created by a wax between the planar workpiece and a support plate, wherein the surfaces of the support plate and of the planar workpiece which are to be joined, after the workpiece has been laid onto the support plate, are only partially covered with wax.

2. The method as claimed in claim 1, wherein the planar workpieces are semiconductor wafers or other workpieces which are to be polished with a high degree of surface planarity.

3. The method as claimed in claim 1 or 2, wherein the wax is applied to one of the surfaces to be joined as a pattern of spots.

4. The method as claimed in claim 1 or 2, wherein the wax is applied to one of the surfaces to be joined as a pattern of strips.

5. The method as claimed in claim 1 or 2, wherein the wax is printed onto one of the surfaces which are to be joined.

6. The method as claimed in one of claims 1 to 5, wherein the wax rises up by a height of from 1 to 50 μm from one of the surfaces to be joined.

7. The method as claimed in one of claims 1 to 6, wherein the covering of the workpiece with wax in an edge region of the workpiece is greater than in a central region of the workpiece.

8. The method as claimed in one of claims 1 to 7, wherein the wax is a mixture of substances based on colophony resin.

9. The method as claimed in one of claims 1 to 8, wherein at most 75% of the surfaces to be joined are covered with wax when the workpiece is resting on the support plate.

10. The method as claimed in claim 9, wherein from 10 to 50% of the surfaces to be joined is covered with wax.

11. The method as claimed in one of claims 1 to 10, wherein the workpiece, when it is being laid onto the support plate, is dropped onto the support plate in a convexly deformed state.

12. The method as claimed in one of claims 1 to 11, wherein the workpiece, after it has been placed onto the support plate, is pressed onto the support plate under a pressure of from 50 to 1000 mbar.
